(19) United States
(12) Patent Application Publication
(10) Pub. No.: US 2025/0165148 A1
(43) Pub. Date: May 22, 2025

(54) PREDICTION OF DATA RETENTION DEGRADATION OF A NON-VOLATILE MEMORY DEVICE BASED ON A MACHINE LEARNING ALGORITHM

(71) Applicant: Microchip Technology Incorporated, Chandler, AZ (US)

(72) Inventors: Pitamber SHUKLA, San Jose, CA (US); Chris NORRIE, Castro Valley, CA (US); Igor ZIPER, Sunnyvale, CA (US)

(21) Appl. No.: 18/622,866

(22) Filed: Mar. 29, 2024

Related U.S. Application Data
(60) Provisional application No. 63/600,033, filed on Nov. 16, 2023.

(51) Int. Cl. G06F 3/06

(52) U.S. Cl. CPC G06F 3/0611; G06F 3/0659; G06F 3/0679

(57) ABSTRACT

A controller, of a solid state drive (SSD), may perform, on one or more blocks of a non-volatile memory device of the SSD, read operations using pre-determined threshold voltages associated with two overlapped charge states. The read operations may be performed after a power-on condition following a power-off condition on the non-volatile memory device. The controller may determine, using a machine learning model, a change in threshold voltages associated with the two overlapped charge states, after the power-off condition. The machine learning model may determine the change in threshold voltages using bit error rates associated with the read operations. The machine learning model may be trained to determine changes in threshold voltages for the two overlapped charge states, after power-off conditions. The controller may determine adjusted threshold voltages associated with the two overlapped charge states based on the change in threshold voltages.

### RELATED APPLICATION

This application claims priority to U.S. Provisional Patent Application No. 63/600,033 entitled “DETERMINING DATA RETENTION DEGRADATION OF A NAND FLASH MEMORY DEVICE BASED ON AN ADAPTIVE MACHINE LEARNING ALGORITHM,” filed Nov. 16, 2023, which is incorporated herein by reference in its entirety.

### FIELD

The present disclosure generally relates to data retention degradation of non-volatile memory devices and, for example, to determining the data retention degradation (of the non-volatile memory devices) using a machine learning model.

### BACKGROUND

A non-volatile memory device may include a memory device that may store and retain data without external power supply. One example of a non-volatile memory device is a not-AND (NAND) flash memory device. In some situations, the non-volatile memory device may be subject to power loss. The power loss may cause the non-volatile memory device to experience data retention degradation (e.g., to experience loss of electrons from a floating gate or a charge trap layer of the non-volatile memory device).

### SUMMARY

In some implementations, a method performed by a controller of a solid state drive (SSD), the method comprising performing, on one or more blocks of a non-volatile memory device of the SSD, read operations using pre-determined threshold voltages associated with two overlapped charge states, wherein the read operations are performed after a power-on condition following a power-off condition on the non-volatile memory device; determining, using a machine learning model, a change in threshold voltages associated with the two overlapped charge states, after the power-off condition, wherein the machine learning model determines the change in threshold voltages using bit error rates associated with the read operations, wherein the machine learning model is trained using characterization data that identifies different changes in threshold voltages for different data retention conditions for the two overlapped charge states of one or more non-volatile memory devices, and wherein the machine learning model is trained to determine changes in threshold voltages for the two overlapped charge states, after power-off conditions; and determining adjusted threshold voltages associated with the two overlapped charge states based on the change in threshold voltages, wherein subsequent read operations are performed on the one or more blocks using the adjusted threshold voltages.

In some implementations, a system comprising: a controller, of a non-volatile memory device, to: detect read errors based on read operations performed using pre-determined threshold voltages associated with two overlapped charge states, wherein the read operations are performed, on a non-volatile memory device, after a power-on condition following a power-off condition on the non-volatile memory device; determine, using a machine learning model, a change in threshold voltages associated with the two overlapped charge states after the power-off condition, wherein the change in threshold voltages is determined based on detecting the read errors, wherein the machine learning model is trained using characterization data that identifies different changes in threshold voltages for different data retention conditions for the two overlapped charge states of one or more non-volatile memory devices, and wherein the machine learning model is trained to determine changes in threshold voltages for the two overlapped charge states after power-on conditions following power-off conditions; and adjust, based on the change in threshold voltages, the pre-determined threshold voltages to obtain adjusted threshold voltages, wherein subsequent read operations are performed on the non-volatile memory device using the adjusted threshold voltages.

In some implementations, a computer program product comprising: one or more computer readable storage media, and program instructions collectively stored on the one or more computer readable storage media, the program instructions comprising: program instructions to detect read errors based on read operations performed using threshold voltages associated with two overlapped charge states, wherein the read operations are performed after a power-on condition following a power-off condition on a non-volatile memory device, and wherein the read operations are performed on one or more blocks of the non-volatile memory device; and program instructions to determine, using a machine learning model, a change in threshold voltages associated with the two overlapped charge states after the power-off condition, wherein the machine learning model is trained using characterization data that identifies different changes in threshold voltages for different data retention conditions for the two overlapped charge states of one or more non-volatile memory devices, wherein the machine learning model is trained to determine changes in threshold voltages for the two overlapped charge states, after power-off conditions, and wherein subsequent read operations are performed on the one or more blocks based on the change in threshold voltages.

### BRIEF DESCRIPTION OF THE DRAWINGS

FIGS. 1A-1H are diagrams of an example implementation described herein.

FIG. 2 is a diagram of example components of one or more devices of FIGS. 1A-1H.

FIGS. 3A and 3B are flowcharts of an example process associated with determining data retention degradation using a machine learning model.

FIGS. 4A and 4B are flowcharts of an example process associated with determining data retention degradation using a machine learning model.

### DETAILED DESCRIPTION

The following detailed description of example implementations refers to the accompanying drawings. The same reference numbers in different drawings may identify the same or similar elements.

In some situations, the non-volatile memory device may be subject to a power-off condition. In some examples, the power loss may be an asynchronous power loss. For example, the power loss may be unexpected or sudden. In some examples, the power loss may be a synchronous power loss. For example, the power loss may be expected. A not-AND (NAND) memory device is a type of non-volatile memory device.

Over a period of time, as the non-volatile memory device is under various environmental conditions during the power loss, electrons stored in different cells (e.g., of the non-volatile memory device) may migrate. For instance, over a period of time, as the non-volatile memory device is subject to temperatures (that may increase), a loss of electrons (e.g., stored in charge trap layers or floating gates of the different cells) may occur.

The migration of the electrons may cause initial threshold voltages of different charge states (of the different cells) to change to subsequent threshold voltages (which are unknown threshold voltages). Accordingly, attempts to read data (e.g., stored by the cells) using the initial threshold voltages may result in errors. In this regard, the unknown threshold voltages (resulting from the data retention degradation) may cause read errors during attempts to read data using the initial threshold voltages (or default read levels set by the non-volatile memory device). For example, attempts to read data (using the initial threshold voltages instead of the unknown threshold voltages) may cause read errors.

In some situations, the read errors may increase the bit error rate (BER). The increased BER may cause increased read latency. For example, as a result of the increased BER, multiple attempts may be made to decode bits associated with the increased BERs. A controller may attempt to decode the bits using complex algorithms, which may include iterative decoding attempts. Attempting to decode the bits with the increased BER is a time consuming task. Accordingly, the increase in the BER may cause read latency in subsequent read operations. Additionally, an increased BER may also overwhelm a decoding circuit such that the decoding circuit fails to find and correct all the errors. The failure to find and correct all the errors may lead to data loss.

In some situations, the loss of electrons during the power-off condition may cause delays with respect to performing a block refresh operation. During the block refresh operation, data written in a first memory block (or “block”) may be written to a second memory block. If the block refresh operation is not timely performed on the first memory block, the first memory block may be subject to data loss.

For at least the foregoing reasons, preventing the read errors after the power-off condition may reduce the read latency in read operations subsequent to the power-off condition. Additionally, for at least the foregoing reasons, prioritizing block refresh operations may prevent future data loss.

Implementations described herein reduce read latency in read operations that occur subsequent to a power-off condition experienced by a memory device. Implementations described herein may maintain or improve data integrity of the memory device subsequent to the power-off condition. In other words, implementations described herein provide a technical solution to the technical problem of reducing read latency in read operations that occur subsequent to a power-off condition experienced by the memory device. Additionally, implementations described herein provide a technical solution to the technical problem of maintaining or even improving data integrity of the memory device. Furthermore, implementations described herein provide a technical solution to the technical problem of avoiding data loss due to too many bit errors, making the errors uncorrectable.

In this regard, implementations described herein are directed to determining data retention degradation (after a power-off condition) using one or more machine learning models. As used herein, “data retention degradation” may be used to refer to a degraded (or decreased) data retention of the memory device due to loss of electrons occurring during a power-off condition of the memory device. The loss of electrons may affect threshold voltages. Accordingly, “data retention degradation” may indicate a change in threshold voltages as a result of the loss of electrons. The one or more machine learning models may be trained using characterization data regarding one or more non-volatile memory devices. The characterization data may identify different changes in threshold voltages for different data retention conditions for two overlapped charge states. For example, the characterization data may identify different threshold voltages (associated with the two overlapped charge states) as a result of different temperatures over different periods of time after different program/erase cycles. A threshold voltage may be a voltage used to read data stored by a memory cell of a non-volatile memory device, such as a NAND flash memory device.

As used herein, “overlapped charge states” may refer to adjacent charge states, as described herein. For example, overlapped charges states may refer to charge states with threshold voltage windows that may overlap. In some examples, the two overlapped charge states may be associated with highest threshold voltages. Because the two overlapped charge states are associated with highest threshold voltages and, hence, highest number of electrons, the two overlapped charge states are more susceptible to the highest number of loss of electrons. Because the two overlapped charge states are more susceptible to the highest number of loss of electrons, knowing the data retention degradation of the two overlapped charge states may provide insight into the data retention degradation of other charge states (e.g., provide information that may be used to determine the data retention degradation of other charge states). Therefore, implementations described herein improve the reliability of reading any of the charge states in a non-volatile memory cell, such as a flash memory cell.

In some situations, loss of electrons of the other charge states may be determined based on loss of electrons of the two overlapped charge states in conjunction with the characterization data. For example, adjusted (or corrected) read level corresponding to the two overlapped charge states may be determined using a machine learning model. The adjusted read level may be used to determine adjusted read levels for other charge states using a predetermined mathematical equation or using a lookup table based on the characterization data. How the other lower threshold voltages degraded could also be determined by the machine learning algorithm. In other words, reading the two overlapped charge states from the cell, putting that data into the machine learning inference, and reading the output of the machine learning inference may provide all threshold voltages for the other charge states, not just the two overlapped charge states. A signature regarding loss of electrons for the two overlapped charge states may be used to determine a signature regarding loss of electrons for other charge states.

The one or more machine learning models may be trained by one or more computing devices that are to train machine learning models. In this regard, the one or more computing devices may determine different threshold voltages (in the particular range) after the one or more non-volatile memory devices have been heated to different temperatures over different periods of time. The characterization data may identify the different threshold voltages, the different temperatures, and the different periods of time.

In some situations, the one or more non-volatile memory devices may have undergone different program/erase cycles. In this regard, the characterization data may identify different program/erase cycles associated with the different temperatures, associated with different amounts of times, or associated with different threshold voltages. The one or more computing devices may train the one or more machine learning models using the characterization data. In some examples, the one or more machine learning models may receive bit error rates corresponding to pre-determined threshold voltages as inputs and perform a regression analysis to determine an adjustment to threshold voltages as an output. In some implementations, the pre-determined threshold voltages may include threshold voltages predetermined by a manufacturer of the non-volatile memory devices.

In some examples, the one or more computing devices may train a single machine learning model (e.g., a single neural network) using the characterization data that identifies one or more of the different threshold voltages, the different temperatures, the different periods of time, or the different program/erase cycles, among other examples. In some examples, the one or more computing devices may train different machine learning models for different program/erase cycles. For example, the one or more computing devices may train a first machine learning model using different threshold voltages for a first number of program/erase cycles as a result of first temperatures, train a second machine learning model using different threshold voltages for a second number of program/erase cycles as a result of second temperatures, and so on. In this regard, different machine learning models may be trained using different respective temperature profiles across different program/erase cycles in different possible combinations.

After training the one or more machine learning models, the one or more computing devices may provide the one or more trained machine learning models to a controller of a non-volatile memory device. For example, the controller may be a firmware microcontroller (e.g., a controller that performs operations using firmware). The controller may use the one or more trained machine learning models to determine a data retention degradation of the non-volatile memory device.

For example, the controller may use the one or more trained machine learning models to determine a data retention degradation of the particular range (associated with the two overlapped charge states) after a power-off condition. In some situations, during a power-on condition following a power-off condition, the controller may perform read operations for one or more blocks (or memory blocks) of the non-volatile memory device. In some examples, the controller and the non-volatile memory device may be included in a solid-state drive (SSD). The controller may perform the read operations using pre-determined threshold voltages included in the particular range of threshold voltages associated with the two overlapped charge states. As a result of performing the read operations using the pre-determined threshold voltages during the power-on condition, read errors may occur because of the data retention degradation that occurred during the power-off condition (e.g., because of the change in threshold voltages as a result of the loss of electrons that occurred during the power-off condition).

In some examples, the one or more blocks may be pre-identified before the power-off conditions. For instance, the one or more blocks may be blocks that are periodically subject to program/erase cycles. For example, the one or more blocks may be programmed and erased every ten hours or every twenty four hours, among other examples. In some examples, the controller may maintain program/erase information identifying dates and times of program/erase cycles of a plurality of blocks of the non-volatile memory device. The controller may analyze the program/erase information to identify the one or more blocks as blocks with most recent program/erase cycles.

In some examples, the one or more blocks may be randomly selected. The controller may determine an average of the threshold voltages used to perform the read operations on the one or more blocks. Alternatively, the controller may determine a median of the threshold voltages used to perform the read operations on the one or more blocks. Alternatively, the controller may determine a mean of the threshold voltages used to perform the read operations on the one or more blocks.

The controller may use bit errors corresponding to the pre-determined threshold voltages (used to perform the read operations) as inputs to the one or more machine learning models. In some situations, the controller may identify the number of program/erase cycles of the one or more blocks and may select a machine learning model trained using a portion of the characterization data, e.g., threshold voltages, corresponding to the number of program/erase cycles. Alternatively, the controller may select a machine learning model trained using an entirety of the characterization data.

The selected machine learning model may provide, as an output, a determined data retention degradation associated with the two overlapped charge states (e.g., associated with the particular range of threshold voltages). For example, the selected machine learning model may determine adjusted threshold voltages associated with the two overlapped charge states after the power-off condition (e.g., adjusted threshold voltages to be used during a power-on condition following the power-off condition). The determined data retention degradation may indicate a change in threshold voltages associated with the pre-determined threshold voltages. In this regard, the determined data retention degradation may indicate a change between the pre-determined threshold voltages and the adjusted threshold voltages.

The controller may use the change to determine adjusted threshold voltages for other charge states. In some examples, the controller may determine adjusted threshold voltages for the other charge states by performing a lookup of a data structure (e.g., a lookup table). For example, the data structure may store information identifying different threshold voltages for the two overlapped charge states in association with different threshold voltages for a first one of for the other charge states, store information identifying different threshold voltages for the two overlapped charge states in association with different threshold voltages for a second one of the other charge states, and so on.

In some examples, the controller may determine adjusted threshold voltages for the other charge states using a mathematical operation. For example, the mathematical operation may indicate a relationship between threshold voltages of the two overlapped charge states and threshold voltages of the other charge states. The mathematical operation may include a linear equation, or a non-linear equation, among other examples.

The controller may use the adjusted threshold voltages to perform the read operations until a read error occurs. Upon occurrence of the read error, the controller may use the selected machine learning model to determine new adjusted threshold voltages. Read operations may be performed on an entire word line to acquire a full codeword of data, thereby determining how many errors may be in a word line. If the content of a word line is known, this may prevent performing a read operation on all the word lines of a codeword in order to count the errors. A comparison may be made between what was read versus what was expected to read, and the bit errors may be manually counted.

In some examples, the non-volatile memory device may be a triple-level cell (TLC) memory device. While some examples described herein are directed to TLC memory devices, implementations described herein are applicable to other types of non-volatile memory devices or other non-volatile memory devices.

By determining the data retention degradation as disclosed herein, implementations described herein may reduce delays associated with read operations. Additionally, determining the data retention degradation as disclosed herein, implementations described herein may accurately monitor the health data of memory blocks and, accordingly, enable block refresh operations to be timely performed for the memory blocks. By enabling the block refresh operations to be timely performed for the memory blocks, implementations described may maintain data integrity of the non-volatile memory device and may prevent data loss of the non-volatile memory device.

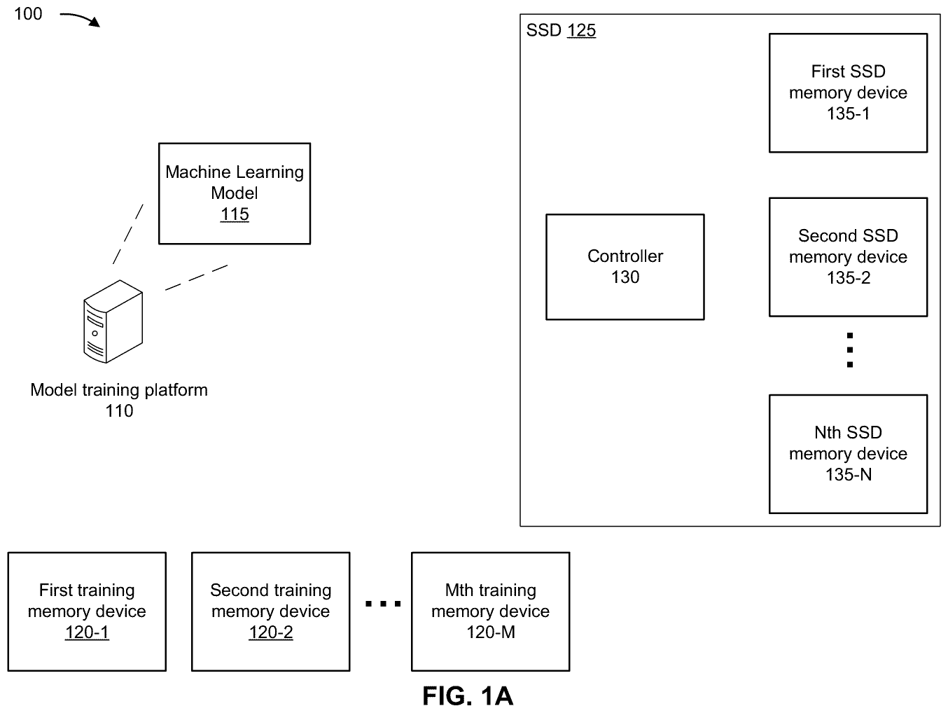

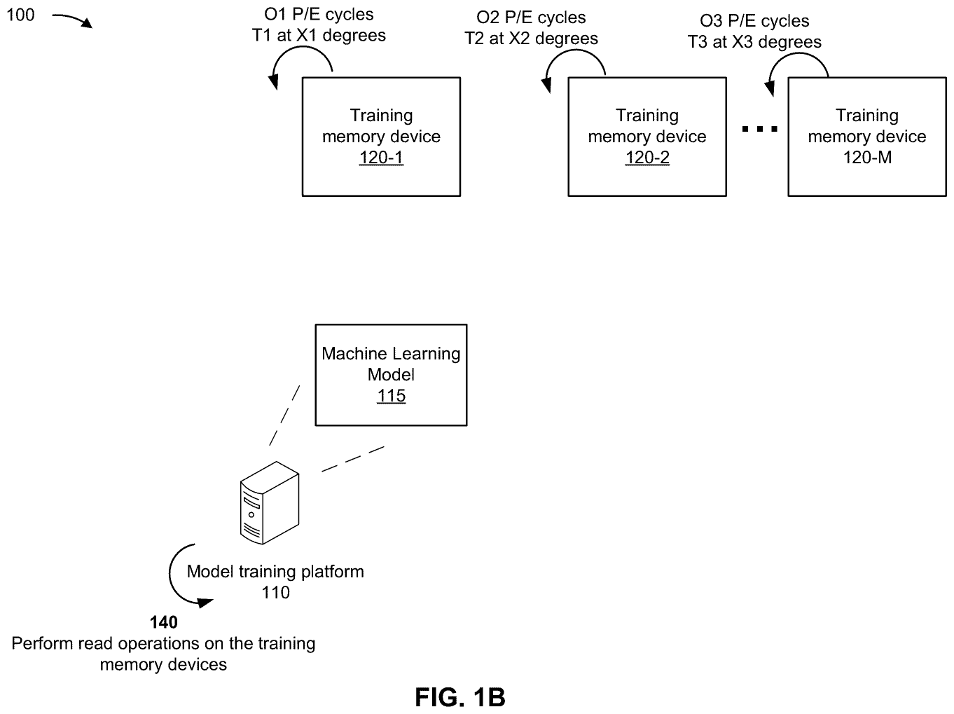

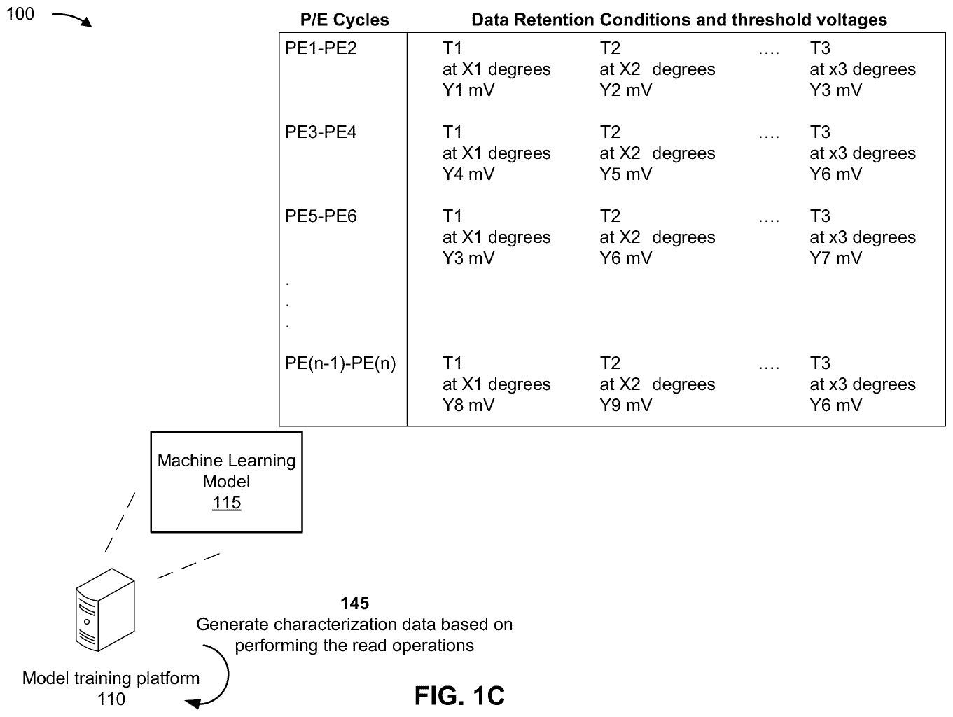

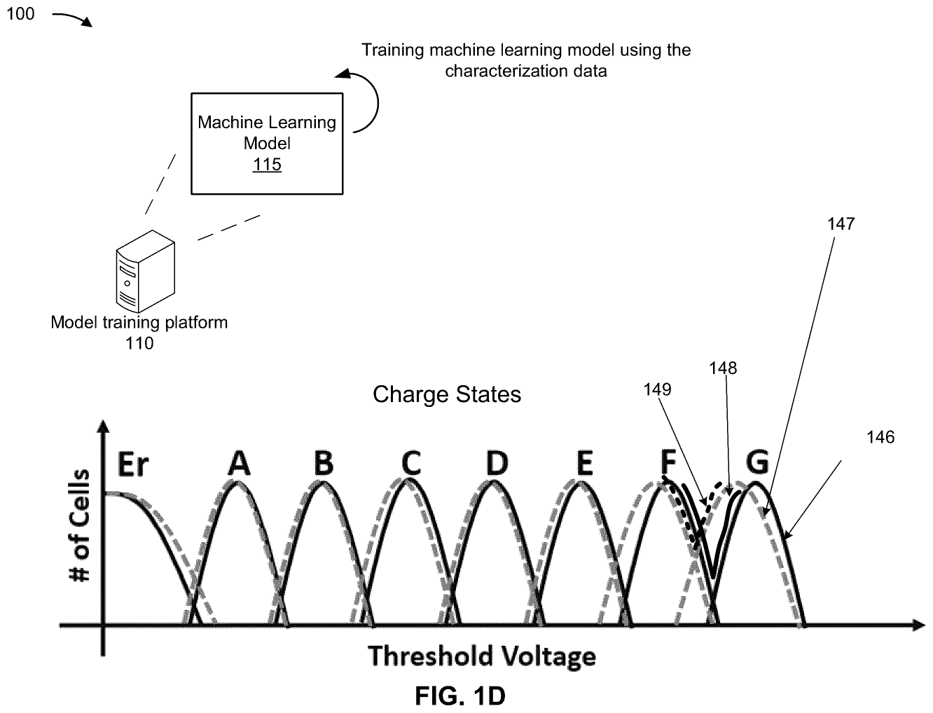

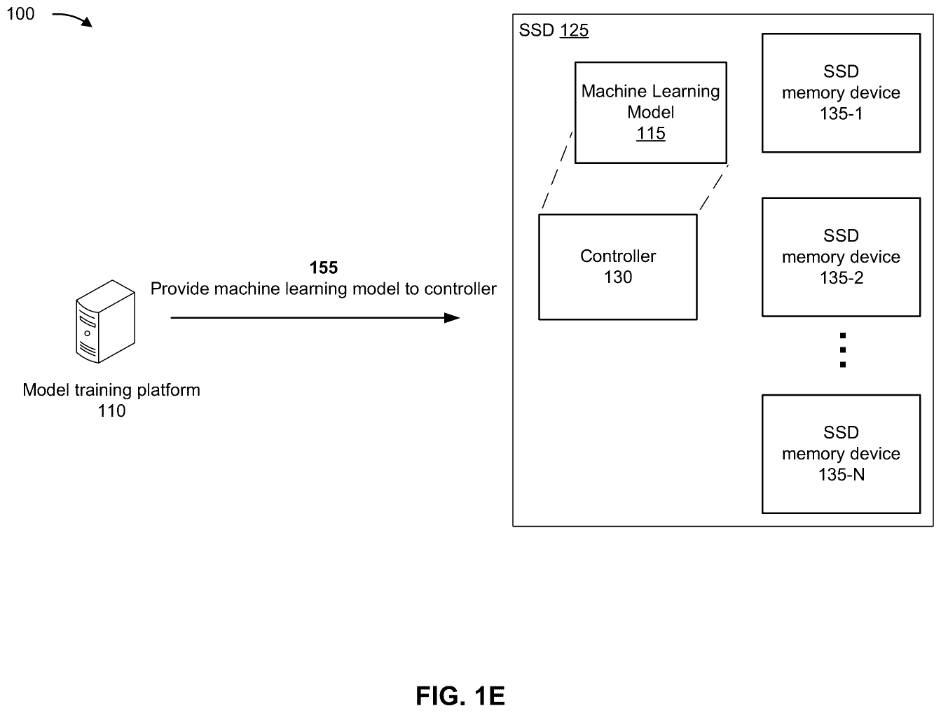

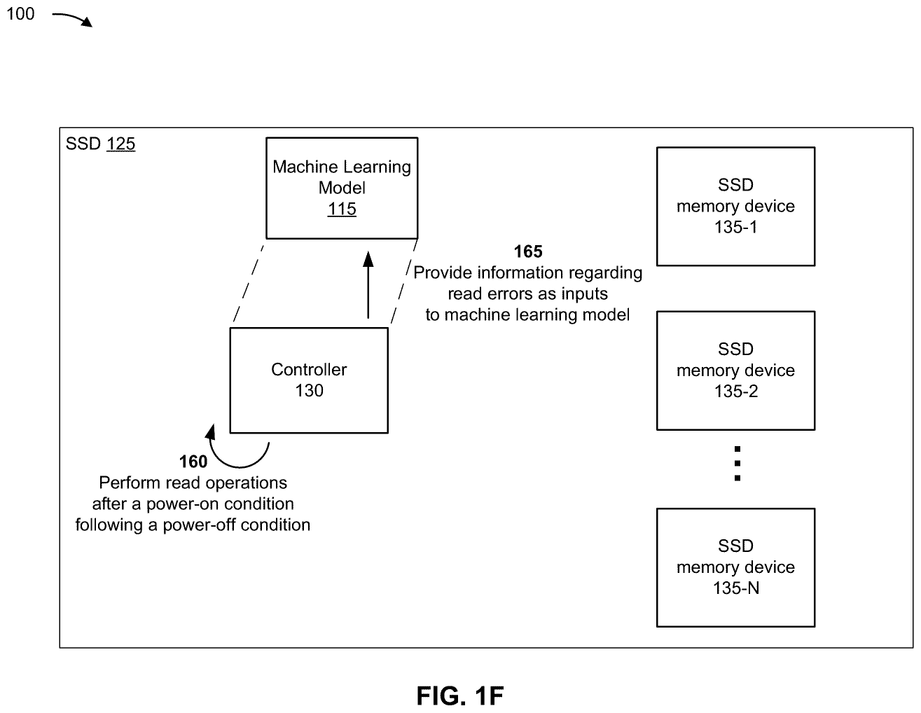

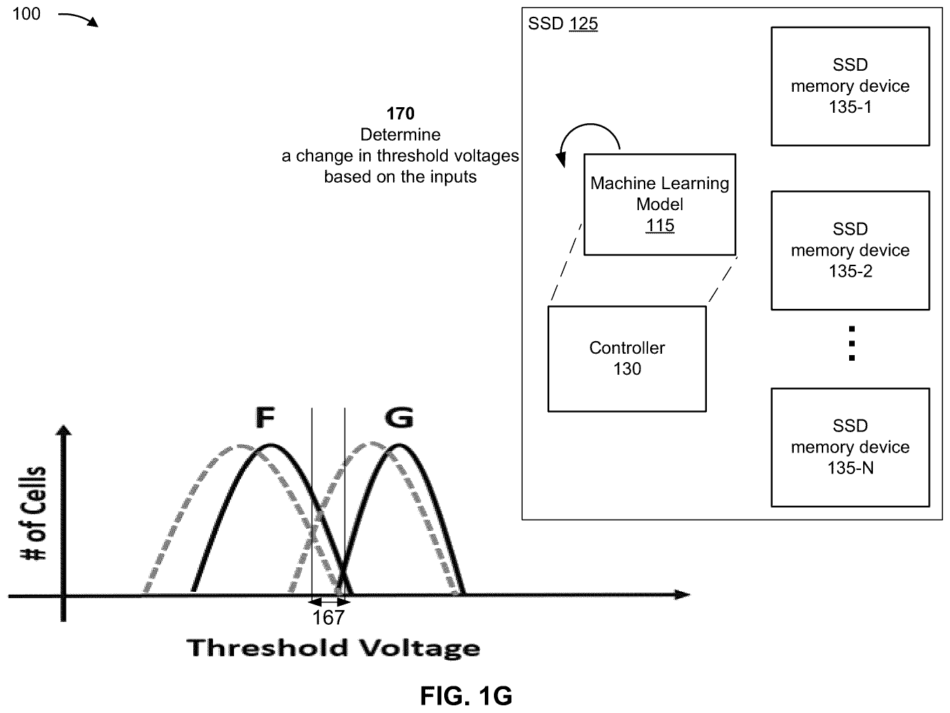

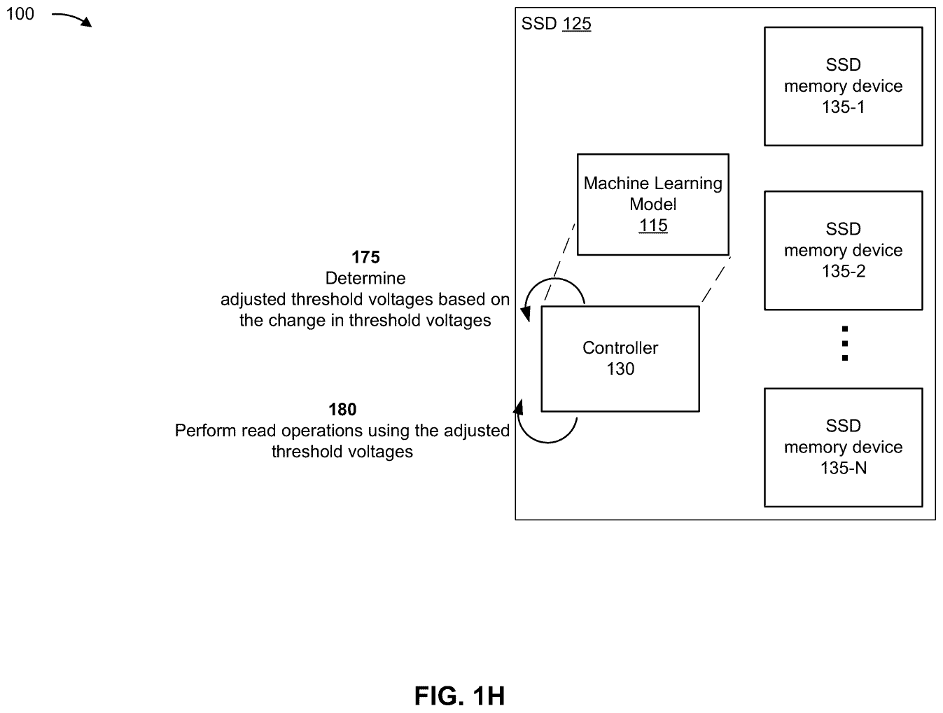

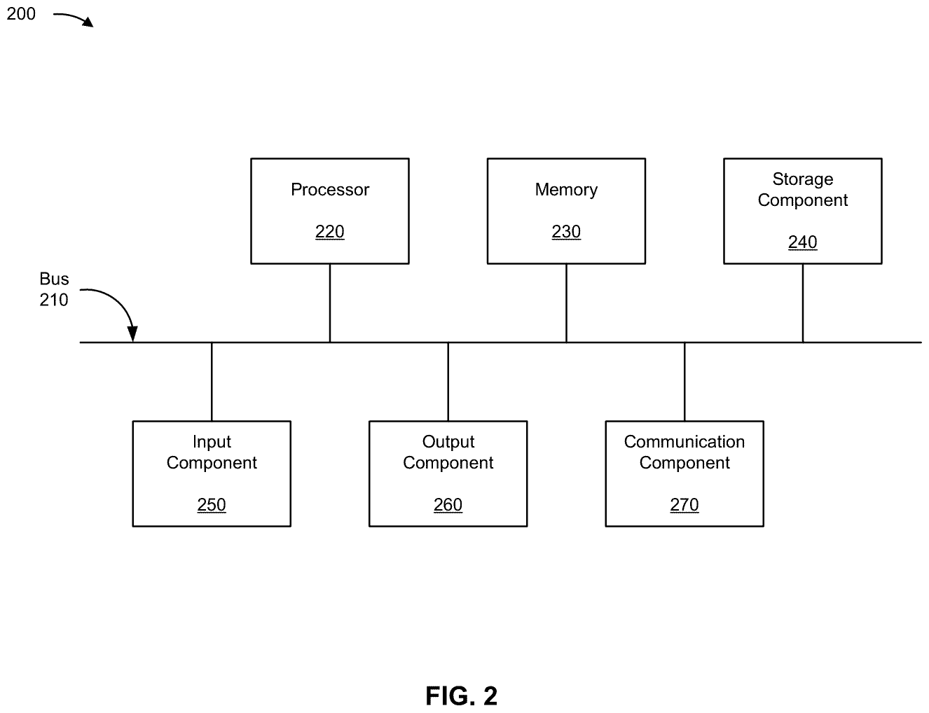

FIGS. 1A-1H are diagrams of an example implementation 100 associated with determining data retention degradation described herein. As shown in FIG. 1, example implementation 100 includes model training platform 110 which may include a machine learning model 115, a first training memory device 120-1, a second training memory device 120-2, up to an mth training memory device 120-M (collectively “memory devices 120” and individually “memory device 120”), and an SSD 125. These devices are described below in connection with FIG. 2.

Model training platform 110 may include one or more devices to train one or more machine learning models, as explained herein. Model training platform 110 may include a communication device and a computing device. For example, model training platform 110 may include a server, a laptop computer, a desktop computer, or a similar type of device. In some implementations, model training platform 110 may be a computing device that is part of a computing environment. The communication device may include an interface for communicating with other devices and the computing device may include a combination of one or more processors, controllers, firmware, software, and/or other logic configured to execute computing operations.

As shown in FIG. 1A, model training platform 110 may include machine learning model 115. Model training platform 110 may train machine learning model 115 and provide machine learning model 115 to a controller 130 of SSD 125. In some situations, model training platform 110 may include multiple machine learning models 115. In this regard, model training platform 110 may train and provide one or more machine learning models 115 to SSD 125.

Machine learning model 115 may be trained to determine a data retention degradation of non-volatile memory devices. For example, machine learning model 115 may be trained to determine a change in pre-determined threshold voltages of a non-volatile memory device as a result of a data retention degradation experienced by the non-volatile memory device. The change may occur after a power off condition experienced by the non-volatile memory device. In some examples, machine learning model 115 may include a neural network model.

A training memory device 120 may include a non-volatile memory device, such as a flash memory device. The training memory device 120 may include a TLC non-volatile memory device, e.g., a TLC NAND flash memory device. Alternatively, the training memory device 120 may include a single-level cell (SLC) non-volatile memory device, e.g., an SLC NAND flash memory device. Alternatively, the training non-volatile memory device 120 may include a multi-level cell (MLC) memory device, e.g., an MLC NAND flash memory device. Alternatively, the training memory device 120 may include a quad-level cell (QLC) non-volatile memory device, e.g., a QLC NAND flash memory device. The training memory device 120 may be used to generate characterization data (e.g., training data) that is used to train machine learning model 115. In some examples, the characterization data may include different bit error rates corresponding to different threshold voltages used to perform read operations on the training memory device 120.

SSD 125 may include a solid-state memory device. As shown in FIG. 1A, SSD 125 may include a controller 130, a first SSD memory device 135-1, a second SSD memory device 135-2, up to an nth SSD memory device 135-N (collectively “SSD memory devices 135” and individually “SSD memory device 135”).

Controller 130 may include one or more devices to perform operations on SSD memory devices 135. For example, controller 130 may perform read operations, program (write) operations, and erase operations. In some examples, controller 130 may include an application-specific integrated circuit (ASIC) controller. In some examples, controller 130 may include a microcontroller. For example, controller 130 may perform operation using firmware stored on a memory of controller 130 (e.g., stored on a random access memory).

In some examples, controller 130 may determine threshold voltages that are used to perform read operations on SSD memory devices 135 after power-off conditions). In some situations, controller 130 may receive machine learning model 115 from model training platform 110 after machine learning model 115 has been trained and may use machine learning model 115 to determine adjusted threshold voltages to be used during a power-on condition following the power-off condition (e.g., determine changes to threshold voltages).

An SSD memory device 135 may include a non-volatile memory device, such as a flash memory device. The SSD memory device 135 may store data of a host computing device (not shown) connected to SSD 125. The SSD memory device 135 may include a TLC non-volatile memory device, an SLC non-volatile memory device, or an MLC non-volatile memory device.

While examples herein may be described with respect to NAND flash memory device, implementations described herein may be applicable to other types of non-volatile memory devices, such as ferroelectric random-access memory (FeRAM), magnetic random-access memory (MRAM), phase-change memory (PCM), or NOR flash memory devices, among other examples.

As shown in FIG. 1B, training memory devices 120 may experience different program/erase cycles and may be subject to different data retention conditions. In other words, training memory devices 120 may be subject to different temperatures over different periods of time. For example, first training memory device 120-1 may experience a first number of program/erase cycles and may be subject to a first temperature over a first period of time, second training memory device 120-1 may experience a second number of program/erase cycles and may be subject to a second temperature over a second period of time, and so on. The data retention conditions may cause training memory devices 120 to experience data degradation. In other words, training memory devices 120 may experience losses of electrons.

As shown in FIG. 1B, and by reference number 140, model training platform 110 may perform read operations on the training memory devices. In some implementations, after training memory devices 120 have experienced different program/erase cycles and have been subject to different data retention conditions (e.g., different temperatures over different periods of time), read operations may be performed on training memory devices 120. In some situations, the read operations may be performed by controllers provided with training memory devices 120. Alternatively, the read operations may be performed by model training platform 110.

As an example, multiple read operations may be performed on first training memory device 120-1 using first pre-determined threshold voltages. The first pre-determined threshold voltages may be included in in a first range of threshold voltages for a first charge state and a second range of threshold voltages for a second charge state. The first charge state and the second charge state may be overlapped charge states.

The read operations may be performed using first pre-determined threshold voltages associated with the overlapped charge states. Because first training memory device 120-1 has been subject to data degradation conditions that cause loss of electrons, performing the read operations using the first pre-determined threshold voltages may result in read errors. Therefore, first adjusted threshold voltages lower than the first pre-determined threshold voltages may be used to successfully perform the read operations. In other words, the first pre-determined threshold voltages may be adjusted (e.g., lowered) to the first adjusted threshold voltages in order to successfully perform the read operations. The read operations may be performed on second training memory device 120-2 and on other training memory devices 120 in a similar manner.

In some examples, the two overlapped charge states may be associated with highest threshold voltages of the training memory device 120 and, accordingly, susceptible to a highest number of loss of electrons. Because the two overlapped charge states are more susceptible to the highest number of loss of electrons, knowing the data retention degradation of the two overlapped charge states may provide insight into the data retention degradation of other charge states.

As shown in FIG. 1C, and by reference number 145, model training platform 110 generate characterization data based on performing the read operations. The characterization data may include training data that is used to train machine learning model 115. The characterization data may identify different changes in threshold voltages for different data retention conditions for the two overlapped charge states of one or more training memory devices 120.

With respect to first training memory device 120-1, for example, the characterization data may identify the first number of program/erase cycles, the first temperature, the first period of time, the first pre-determined threshold voltages, and the first adjusted threshold voltages. In this regard, the characterization data may identify a change in threshold voltages (for the overlapped charge states) that may occur as a result of the data retention degradation following the first number of program/erase cycles at the first temperature for the first period of time.

As shown in FIG. 1C, training memory devices 120 may experience different program/erase cycles, defined as program/erase cycle ranges (e.g., PE1-PE2, PE3-PE4, PE5-PE6, and PE(n−1)-PE(n)) and may be subject to different data retention conditions (e.g., different temperatures over different periods of times). The different program/erase cycles and the different data retention conditions may cause different changes for threshold voltages for the overlapped charge states, e.g. for Tl at X1 degrees there may be a change of threshold voltage of Y1 mV for the range of PE1-PE2, and a change of Y4 mV for the range of PE3-PE4. The characterization data may identify different changes for threshold voltages for the overlapped charge states.

As shown in FIG. 1D, and by reference number 150, model training platform 110 may train machine learning model 115 using the characterization data. In some implementations, model training platform 110 may train machine learning model 115 to determine adjusted threshold voltages based on bit error rates corresponding to pre-determined threshold voltages (e.g., based on read errors caused by pre-determined threshold voltages). In other words, machine learning model 115 may be trained to determine changes to threshold voltages to prevent read errors after a memory device have been subject to different program/erase cycles and different data retention conditions. As an example, machine learning model 115 may receive, as an input, bit error rates corresponding to pre-determined threshold voltages that caused read errors, program erase cycles, and temperatures, among other examples. Machine learning model 115 may provide, as an output, information regarding adjusted threshold voltages that prevent read errors.

As shown in FIG. 1D, as an example, the characterization data may identify a first threshold voltage distribution 146 (in solid lines) for first training memory device 120-1 before first training memory device 120-1 is subject to the first data retention condition. The threshold voltage distribution may include different ranges of threshold voltages for different charge states. In some examples, the graph of FIG. 1D may indicate a probability of an individual cell having a particular threshold voltage due to a number of electrons on the floating gate and the charge trap layer. In this regard, the Y-axis may indicate a curve created by an integration of all the individual cells.

As shown in FIG. 1D, as an example, the characterization data may identify a second threshold voltage distribution 147 (in dashed lines) for first training memory device 120-1 after first training memory device 120-1 has been subject to the first data retention condition. The threshold voltage distribution may include different ranges of threshold voltages for different charge states. As shown in FIG. 1D, second threshold voltage distribution 147 may result from a change in first threshold voltage distribution 146 due to the first data retention condition.

Second threshold voltage distribution 147 may result from a shift in first threshold voltage distribution 146 toward lower threshold voltages due to the first data retention condition. In this regard, because the first data retention condition causes loss of electrons in the charge states, the first data retention condition may cause a decrease in the threshold voltages. Accordingly, the first data retention condition may cause a shift in first threshold voltage distribution 146 toward lower threshold voltages.

The overlapped charge states (associated with highest threshold voltages) may store a number of electrons that exceed a number of electrons stored for other charge states (associated with lower threshold voltages). As a result, the first data retention condition may cause more loss of electrons for the overlapped charge states than for other charge states (associated with lower threshold voltages). In this regard, as shown in FIG. 1D, the change in threshold voltages for the highest overlapped charge states may exceed the change in threshold voltages for other charge states associated with lower threshold voltages (e.g., lower charge states). While FIG. 1D illustrates charge states with overlapping threshold voltage windows, in some situations, charge states may be provided with threshold voltage windows that do not overlap. As shown in FIG. 1D, the characterization data may identify a valley 148 between ranges of threshold voltages of the overlapped charge states before the first data retention condition. Valley 148 may identify a range of threshold voltages that includes a first portion of first threshold voltages of a first charge state (e.g., charge state F) and a first portion of second threshold voltages of a second charge state (e.g., charge state G). As shown in FIG. 1D, the characterization data may identify a valley 149 between ranges of threshold voltages of the overlapped charge states after the first data retention condition. Valley 149 may identify a range of threshold voltages that includes a second portion of the first threshold voltages of the first charge state (e.g., charge state F) and a second portion of the second threshold voltages of a second charge state (e.g., charge state G).

Valley 149 may result from a shift in valley 148 similar to second threshold voltage distribution 147 resulting from a shift in first threshold voltage distribution 146 toward lower threshold voltages due to the first data retention condition. By being trained using the characterization data of first training memory device 120-1 for the overlapped charge states, machine learning model 115 may be trained to determine a change in pre-determined threshold voltages (for the overlapped charge states) that may occur as a result of the first data retention condition (e.g., following the first number of program/erase cycles after first training memory device 120-1 has been subject to a particular temperature over a particular period of time). As an example, machine learning model 115 may be trained to determine threshold voltages corresponding to a valley for the overlapped charge states.

By being trained using the characterization data of additional training memory devices 120 for the overlapped charge states, machine learning model 115 may be trained to determine a change in threshold voltages (for the overlapped charge states) that may occur as a result of different data retention condition (e.g., following different numbers of program/erase cycles subsequent to a power-off period). As an example, machine learning model 115 may be trained to determine threshold voltages corresponding to different valleys for the overlapped charge states. While the example described has been provided with respect to determining a change in threshold voltages subsequent to a power-off condition, implementations described herein may be applicable to determining a change in threshold voltages subsequent to a power-on condition.

While the example described has been provided with respect to overlapped charge states with highest threshold voltages, implementations described herein may be applicable to other overlapped charge states. In some implementations, machine learning model 115 may be trained by a computing device other than model training platform 110. In some implementations, model training platform 110 may train multiple machine learning models 115 associated with different program/erase cycles. For example, model training platform 110 may train a first machine learning model using the characterization data of different data retention conditions after a first program/erase cycle (or after a first range of program/erase cycles); may train a second machine learning model using the characterization data of different data retention conditions after a second program/erase cycle (or after a ran range of program/erase cycles); and so on.

As shown in FIG. 1E, and by reference number 155, model training platform 110 may provide a machine learning model (e.g., machine learning model 115) to controller 130. For example, after training machine learning model 115, model training platform 110 may provide machine learning model 115 to the controller 130. In some implementations, controller 130 may use machine learning model 115 to determine adjusted threshold voltages for read operations after SSD 125 (e.g., SSD memory devices 135) experiences a power-off condition.

As shown in FIG. 1F, and by reference number 160, controller 130 may perform read operations after a power-on condition following a power-off condition. For example, model training platform 110 may perform read operations on first SSD memory device 135-1. Controller 130 may perform the read operations using default threshold voltages. The read operations may be performed using the default threshold voltages because when power is restored to SSD 125 following the power-off condition, a default read level may be used as a first guess which was provided by first SSD memory device 135-1. Because of the data retention condition, first SSD memory devices 135-1 may experience some loss of electrons. As a result of the loss of electrons, the threshold voltage used to perform the read operations is to be lowered. Accordingly, performing the read operation using the default threshold voltages may result in read errors. In some situations, the default threshold voltages may include the pre-determined threshold voltages. Controller 130 may perform the read operations to read data associated with the overlapped charge states.

In some implementations, controller 130 may perform the read operations on one or more blocks of first SSD memory device 135-1. In some examples, the one or more blocks may be pre-identified before the power-off conditions. For instance, the one or more blocks may be blocks that are periodically subject to program/erase cycles. For example, the one or more blocks may be programmed and erased every ten hours, or every twenty four hours, among other examples. In some examples, controller 130 may store program/erase information identifying dates and times of program/erase cycles of a plurality of respective blocks of first SSD memory device 135-1. The controller may analyze the program/erase information to identify the one or more blocks as blocks with most recent program/erase cycles. The analysis may be performed to avoid a mix of data degradation and a program/erase cycle degradation signatures.

In some examples, the one or more blocks may be randomly selected. For example, blocks of first SSD memory devices 135-1 may be selected in accordance with wear leveling. According, controller 130 may randomly select the one or more blocks based on wear leveling.

As shown in FIG. 1F, and by reference number 165, controller 130 may provide information regarding the read errors as inputs to machine learning model 115. For example, model training platform 110 may provide (to machine learning model 115) information identifying bit error rates corresponding to the pre-determined threshold voltages.

In some instances, controller 130 may analyze the program/erase information to determine the number of program/erase cycles of the one or more blocks. Controller 130 may select a machine learning model based on the number of program/erase cycles of the one or more blocks. For example, controller 130 may select a machine learning model that has been trained with the characterization data of one or more training memory devices 120 that have experienced the number of program/erase cycles.

As shown in FIG. 1G, and by reference number 170, controller 130 may determine a change in threshold voltages based on the inputs. For example, controller 130 may use machine learning model 115 to determine the change regarding the pre-determined threshold voltages. In some implementations, machine learning model 115 may use bit error rates corresponding to the pre-determined threshold voltages (provided as inputs) to determine a valley of the overlapped charge states after first SSD memory devices 135-1 has been subject to data retention conditions. For example, machine learning model 115 may determine a shape of the valley of the overlapped charge states.

Machine learning model 115 may recognize the shape of the valley as pattern of threshold voltages (or signature of threshold voltages) a non-volatile memory device that has been subjected to the particular data retention condition. Machine learning model 115 may use the inputs to determine a change that typically occurs in the threshold voltages for the shape of the valley of the overlapped charge states. In some examples, an internal state of machine learning model 115 may be affected by the shape of the valley in such a way that the output of machine learning model 115 is the result of that changed shape. As shown in FIG. 1G, machine learning model 115 may determine that a change 167 is a change that typically occurs (e.g., based on current conditions) in the threshold voltages to be performed to prevent read errors.

As shown in FIG. 1H, and by reference number 175, controller 130 may determine adjusted threshold voltages based on the change in threshold voltages. For example, machine learning model 115 may adjust threshold voltages based on change 167 (FIG. 1G) to obtain adjusted threshold voltages. For instance, machine learning model 115 may lower the default threshold voltages of the overlapped states by an amount identified by change 167 and may provide the lowered default threshold voltages as an output. In some situations, machine learning model 115 may provide information change 167 to controller 130 and controller 130 may determine the adjusted threshold voltages based on change 167.

In some instances, controller 130 utilizing machine learning model 115 may determine adjusted threshold voltages for other charge states of first SSD memory devices 135-1. In some examples, controller 130 utilizing machine learning model 115 may generate a data structure (e.g., a table) that stores different adjusted threshold voltages of the overlapped charge states in association with corresponding adjusted threshold voltages of other charge states. In this regard, controller 130 may perform a lookup operation of the data structure to determine the adjusted threshold voltages of the other charge states. Alternatively, controller 130 utilizing machine learning model 115 may use a mathematical operation to determine the adjusted threshold voltages for the other charge states. For example, controller 130 or machine learning model 115 may have previously determined the mathematical operation using threshold voltages of one or more training memory devices 120 of the overlapped charge states and of the other charge states.

As shown in FIG. 1H, and by reference number 180, controller 130 may perform read operations using the adjusted threshold voltages. For example, controller 130 may perform the read operations using the adjusted threshold voltages.

In some situations, controller 130 may use an output of machine learning model 115 to monitor the health of data of memory blocks of first SSD memory devices 135-1. For example, as threshold voltages for performing read operations on a memory block are reduced, a data integrity of the memory decreases. For instance, a reduction in the threshold voltages may compromise the integrity of data stored on the memory block or may cause data loss of the data. Accordingly, controller 130 may perform read operations on the memory block and determine, using machine learning model 115, adjusted threshold voltages based on the read operations. Controller 130 may monitor the adjusted threshold voltages to determine whether the adjusted threshold voltages satisfy a threshold. If the adjusted threshold voltages do not satisfy the threshold, controller 130 may determine that the health of the memory block does not satisfy a health threshold and may cause a block refresh operation to be performed on the memory block. Accordingly, machine learning model 115 may enable block refresh operations to be timely performed for memory blocks.

As indicated above, FIGS. 1A-1H are provided as an example. Other examples may differ from what is described with regard to FIGS. 1A-1H. The number and arrangement of devices shown in FIGS. 1A-1H are provided as an example. In practice, there may be additional devices, fewer devices, different devices, or differently arranged devices than those shown in FIGS. 1A-1H. Furthermore, two or more devices shown in FIGS. 1A-1H may be implemented within a single device, or a single device shown in FIGS. 1A-1H may be implemented as multiple, distributed devices. Additionally, or alternatively, a set of devices (e.g., one or more devices) shown in FIGS. 1A-1H may perform one or more functions described as being performed by another set of devices shown in FIGS. 1A-1H.

FIG. 2 is a diagram of example components of a device 200, which may correspond to one or more devices of FIG. 1, such as model training platform 110. In some implementations, model training platform 110 may include one or more devices 200 and one or more components of device 200. As shown in FIG. 6, device 200 may include a bus 210, a processor 220, a memory 230, a storage component 240, an input component 250, an output component 260, and a communication component 270.

Bus 210 includes a component that enables wired or wireless communication among the components of device 200. Processor 220 includes a central processing unit, a graphics processing unit, a microprocessor, a controller, a microcontroller, a digital signal processor, a field-programmable gate array, an application-specific integrated circuit, or another type of processing component. Processor 220 is implemented in hardware, firmware, or a combination of hardware and software. In some implementations, processor 220 includes one or more processors capable of being programmed to perform a function. Memory 230 includes a random access memory, a read only memory, or another type of memory (e.g., a flash memory, a magnetic memory, or an optical memory).

Storage component 240 stores information or software related to the operation of device 200. For example, storage component 240 may include a hard disk drive, a magnetic disk drive, an optical disk drive, a solid state disk drive, a compact disc, a digital versatile disc, or another type of non-transitory computer-readable medium. Input component 250 enables device 200 to receive input, such as user input or sensed inputs. For example, input component 250 may include a touch screen, a keyboard, a keypad, a mouse, a button, a microphone, a switch, a sensor, a global positioning system component, an accelerometer, a gyroscope, or an actuator. Output component 260 enables device 200 to provide output, such as via a display, a speaker, or one or more light-emitting diodes. Communication component 270 enables device 200 to communicate with other devices, such as via a wired connection or a wireless connection. For example, communication component 270 may include a receiver, a transmitter, a transceiver, a modem, a network interface card, or an antenna.

Device 200 may perform one or more processes described herein. For example, a non-transitory computer-readable medium (e.g., memory 230 or storage component 240) may store a set of instructions (e.g., one or more instructions, code, software code, or program code) for execution by processor 220. Processor 220 may execute the set of instructions to perform one or more processes described herein. In some implementations, execution of the set of instructions, by one or more processors 220, causes the one or more processors 220 or the device 200 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 2 are provided as an example. Device 200 may include additional components, fewer components, different components, or differently arranged components than those shown in FIG. 2. Additionally, or alternatively, a set of components (e.g., one or more components) of device 200 may perform one or more functions described as being performed by another set of components of device 200.

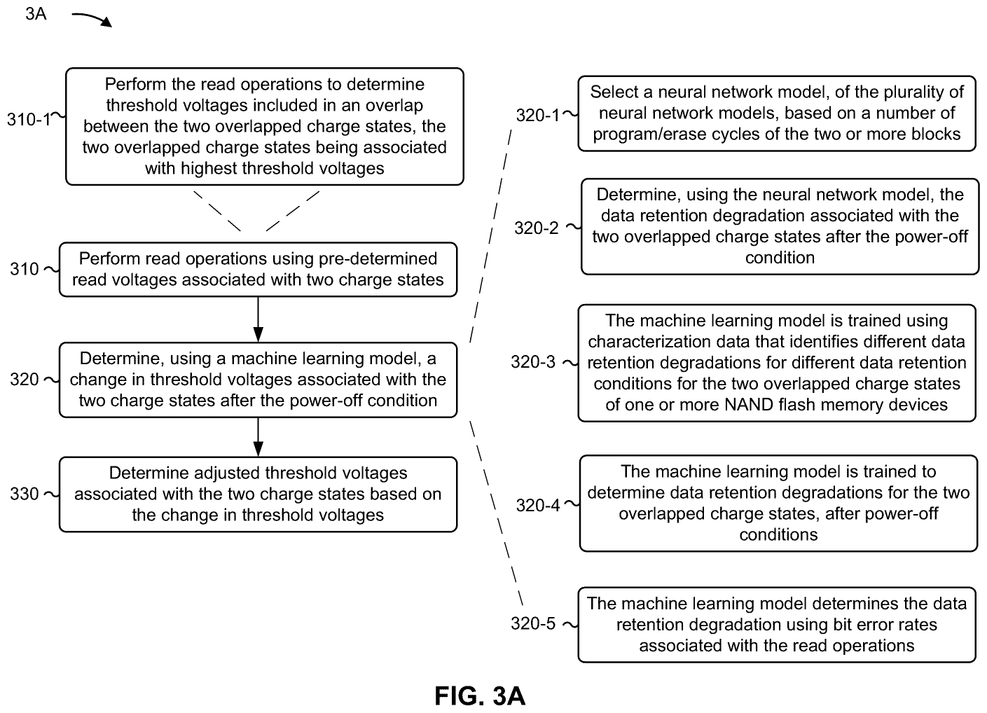

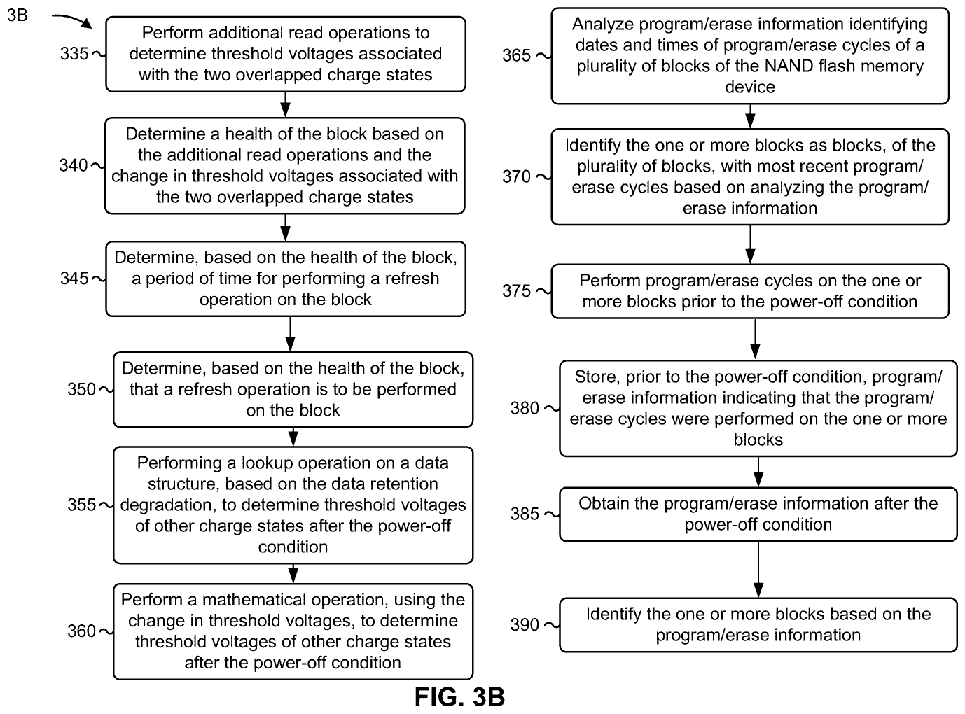

FIG. 3 is a flowchart of an example process 300 associated with improving read results determining data retention degradation using a machine learning model. In some implementations, one or more process blocks of FIG. 3 may be performed by a controller (e.g., controller 130). Additionally, or alternatively, one or more process blocks of FIG. 3 may be performed by one or more components of device 200, such as processor 220, memory 230, storage component 240, input component 250, output component 260, or communication component 270.

As shown in FIG. 3, process 300 may include performing, read operations using pre-determined threshold voltages associated with two overlapped charge states (block 310). For example, the controller may perform, on one or more blocks, read operations using pre-determined threshold voltages associated with two overlapped charge states, wherein the read operations are performed after a power-off condition, as described above.

In some implementations, the read operations are performed after a power-on condition subsequent to a power-off condition that causes a power loss on the NAND flash memory device. In some examples, the read operations are performed in order to generate read errors (e.g., BERs). The read errors may be used as an input to a machine learning model that is trained to determine changes in threshold voltages associated with the overlapped charge states. In some implementations, the method comprises selecting a neural network model, of the plurality of neural network models, based on a number of program/erase cycles of the one or more blocks, and determining, using the neural network model, the change in threshold voltages associated with the two overlapped charge states after the power-off condition.

As further shown in FIG. 3, process 300 may include determining, using a machine learning model, a change in threshold voltages associated with the two overlapped charge states, after the power-off condition (block 320). For example, the controller may determine, using a machine learning model, a change in threshold voltages associated with the two overlapped charge states, after the power-off condition, wherein the machine learning model is trained using characterization data that identifies different changes in threshold voltages for different data retention conditions for the two overlapped charge states of one or more NAND flash memory devices, and wherein the machine learning model is trained to determine changes in threshold voltages for the two overlapped charge states, after power-off conditions, as described above.

In some implementations, the machine learning model may be trained using characterization data that identifies different changes in threshold voltages for different data retention conditions for the two overlapped charge states of one or more NAND flash memory devices. In some implementations, the machine learning model may be trained to determine changes in threshold voltages for the two overlapped charge states, after power-off conditions.

As further shown in FIG. 3, process 300 may include determining adjusted threshold voltages associated with the two overlapped charge states based on the change in threshold voltages (block 330). For example, the controller may determine adjusted threshold voltages associated with the two overlapped charge states based on the change in threshold voltages, wherein the pre-determined threshold voltages are adjusted, based on the change in threshold voltages, to the adjusted threshold voltages, as described above. In some implementations, the pre-determined threshold voltages are adjusted, based on the change in threshold voltages, to the adjusted threshold voltages.

In some implementations, process 300 includes analyzing program/erase information identifying dates and times of program/erase cycles of a plurality of blocks of the NAND flash memory device, and identifying the one or more blocks as blocks, of the plurality of blocks, as blocks with most recent program/erase cycles based on analyzing the program/erase information.

In some implementations, process 300 includes performing program/erase cycles on the one or more blocks prior to the power-off condition, storing, prior to the power-off condition, program/erase information indicating that the program/erase cycles were performed on the one or more blocks, obtaining the program/erase information after the power-off condition, and identifying the one or more blocks based on the program/erase information.

In some implementations, as shown in FIG. 3B, process 300 includes performing, on a block of the non-volatile memory device, the read operations to determine threshold voltages associated with the two overlapped charge states (block 335), determining a health of the block based on the third read operations and the change in threshold voltages associated with the two overlapped charge states (block 340), and determining, based on the health of the block, a period of time for performing a refresh operation on the block (block 345) or determining, based on the health of the block, that a refresh operation is to be performed on the block (block 350).

In some implementations, as shown in FIG. 3B, process 300 includes performing a lookup operation on a data structure, based on the change in threshold voltages, to determine threshold voltages of other charge states after the power-off condition (block 355).

In some implementations, as shown in FIG. 3B, process 300 includes performing a mathematical operation, using the change in threshold voltages, to determine threshold voltages of other charge states after the power-off condition (block 360). The mathematical operation may include a linear equation, a non-linear equation, among other examples.

In some implementations, the power-off condition causes an unexpected loss of power on the non-volatile memory device, and wherein performing the read operations comprises performing, for the one or more blocks, the read operations to determine threshold voltages included in an overlap between the two overlapped charge states, the two overlapped charge states being associated with highest threshold voltages (block 310-1).

In some implementations, process 300 may include analyzing program/erase information identifying dates and times of program/erase cycles of a plurality of blocks of the NAND flash memory device (block 365); and identifying the one or more blocks as blocks, of the plurality of blocks, with most recent program/erase cycles based on analyzing the program/erase information (block 370). In some implementations, process 300 may include performing program/erase cycles on the one or more blocks prior to the power-off condition (block 375); storing, prior to the power-off condition, program/erase information indicating that the program/erase cycles were performed on the one or more blocks (block 380); obtaining the program/erase information after the power-off condition (block 385); and identifying the one or more blocks based on the program/erase information (block 390).

Although FIGS. 3A and 3B show example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

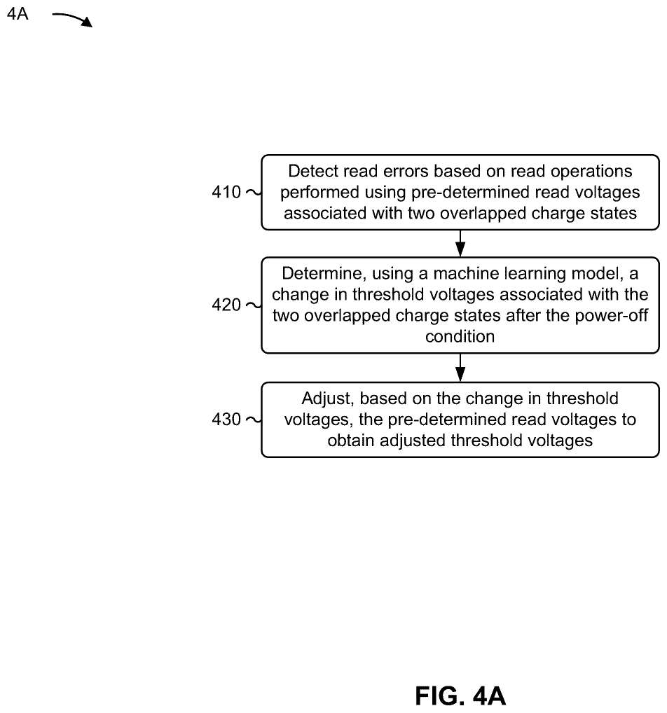

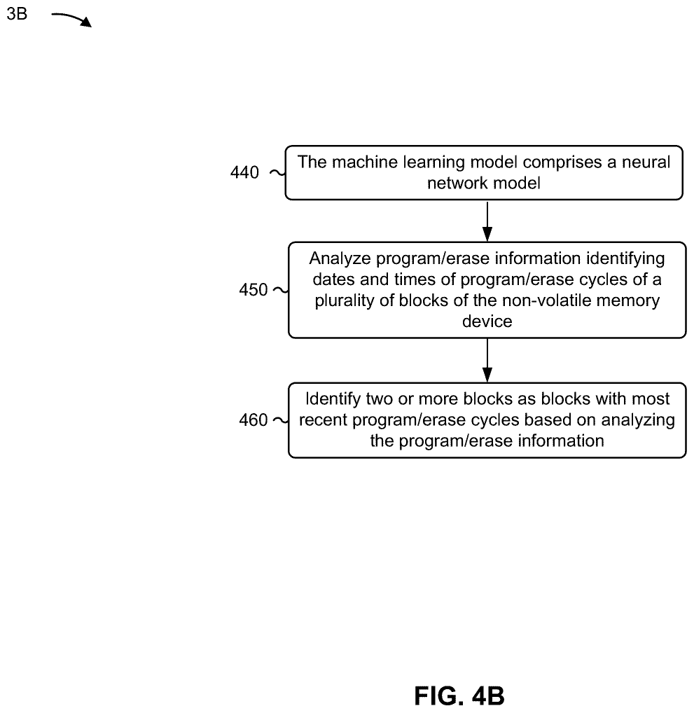

FIGS. 4A and 4B are flowcharts of an example process 400 associated with determining changes in threshold voltages using a machine learning model. In some implementations, one or more process blocks of FIG. 3 may be performed by a controller (e.g., controller 130). Additionally, or alternatively, one or more process blocks of FIG. 4 may be performed by one or more components of device 200, such as processor 220, memory 230, storage component 240, input component 250, output component 260, and/or communication interface 270.

As shown in FIG. 4A, process 400 may include detecting read errors based on read operations performed using pre-determined threshold voltages associated with two overlapped charge states (block 410). For example, the system may detect read errors based on read operations performed using pre-determined threshold voltages associated with two overlapped charge states. The read operations are performed, on the non-volatile memory device, after a power-off condition that causes a power loss on the non-volatile memory device, as described above. In some implementations, the read operations are performed, on the non-volatile memory device, after a power-off condition, i.e. after a subsequent power on of the non-volatile memory device.

As further shown in FIG. 4A, process 400 may include determining, using a machine learning model, a change in threshold voltages associated with the two overlapped charge states after the power-off condition (block 420). For example, the system may determine, using a machine learning model, a change in threshold voltages associated with the two overlapped charge states after the power-off condition. The change in threshold voltages is determined based on detecting the read errors, wherein the machine learning model is trained using characterization data that identifies different changes in threshold voltages for different data retention conditions for the two overlapped charge states of one or more non-volatile memory devices. The machine learning model is trained to determine changes in threshold voltages for the two overlapped charge states after power conditions following power-off conditions, as described above. In some implementations, the change in threshold voltages is determined based on detecting the read errors, the machine learning model is trained using characterization data that identifies different changes in threshold voltages for different data retention conditions for the two overlapped charge states of one or more non-volatile memory devices, and the machine learning model is trained to determine changes in threshold voltages for the two overlapped charge states after power conditions following power-off conditions.

As further shown in FIG. 4A, process 400 may include adjusting, based on the change in threshold voltages, the pre-determined threshold voltages to obtain adjusted threshold voltages (block 430). For example, the system may adjust, based on the change in threshold voltages, the pre-determined threshold voltages to obtain adjusted threshold voltages, as described above.

In some implementations, the machine learning model comprises a neural network model (block 440).

In some implementations, process 400 may include analyzing program/erase information identifying dates and times of program/erase cycles of a plurality of blocks of the non-volatile memory device (block 450), and identifying one or more blocks as blocks with most recent program/erase cycles based on analyzing the program/erase information (block 460).

Although FIGS. 4A and 4B show example blocks of process 400, in some implementations, process 400 may include additional blocks, fewer blocks, different blocks, or differently arranged blocks than those depicted in FIGS. 4A and 4B. Additionally, or alternatively, two or more of the blocks of process 400 may be performed in parallel.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method performed by a controller of a solid state drive (SSD), the method comprising:
performing, on one or more blocks of a non-volatile memory device of the SSD, read operations using pre-determined threshold voltages associated with two overlapped charge states,
wherein the read operations are performed after a power-on condition following a power-off condition on the non-volatile memory device;
determining, using a machine learning model, a change in threshold voltages associated with the two overlapped charge states, after the power-off condition,
wherein the machine learning model determines the change in threshold voltages using bit error rates associated with the read operations,
wherein the machine learning model is trained using characterization data that identifies different changes in threshold voltages for different data retention conditions for the two overlapped charge states of one or more non-volatile memory devices, and
wherein the machine learning model is trained to determine changes in threshold voltages for the two overlapped charge states, after power-off conditions; and
determining adjusted threshold voltages associated with the two overlapped charge states based on the change in threshold voltages,
wherein subsequent read operations are performed on the one or more blocks using the adjusted threshold voltages.

2. The method of claim 1, wherein the characterization data identifies different program/erase cycles associated with the different data retention conditions,
wherein the machine learning model comprises a plurality of neural network models associated with the different program/erase cycles, and
wherein the method comprises:
selecting a neural network model, of the plurality of neural network models, based on a number of program/erase cycles of the one or more blocks; and
determining, using the selected neural network model, the changes in threshold voltage associated with the two overlapped charge states after the power-off condition.

3. The method of claim 1, comprising:
analyzing program/erase information identifying dates and times of program/erase cycles of a plurality of blocks of the non-volatile memory device; and
identifying the one or more blocks as blocks, of the plurality of blocks, with most recent program/erase cycles based on analyzing the program/erase information.

4. The method of claim 1, comprising:
performing program/erase cycles on the one or more blocks prior to the power-off condition;
storing, prior to the power-off condition, program/erase information indicating that the program/erase cycles were performed on the one or more blocks;
obtaining the program/erase information after the power-off condition; and
identifying the one or more blocks based on the program/erase information.

5. The method of claim 1, comprising:
performing, for a block of memory of the non-volatile memory device, additional read operations to determine threshold voltages associated with the two overlapped charge states;
determining a health of the block based on the additional read operations and the change in threshold voltages associated with the two overlapped charge states; and
determine, based on the health of the block, a period of time for performing a refresh operation on the block.

6. The method of claim 1, comprising:
performing a lookup operation on a data structure, based on the change in threshold voltages, to determine threshold voltages of other charge states after the power-off condition.

7. The method of claim 1, comprising:
performing a mathematical operation, using the change in threshold voltages, to determine threshold voltages of other charge states after the power-off condition.

8. The method of claim 1, wherein the power-off condition causes an unexpected loss of power on the non-volatile memory device, and
wherein performing the read operations comprises:
performing, for the one or more blocks, the read operations to determine threshold voltages included in an overlap between the two overlapped charge states,
wherein the two overlapped charge states are associated with highest threshold voltages.

9. A system comprising:
a controller to:
detect read errors based on read operations performed using pre-determined threshold voltages associated with two overlapped charge states,
wherein the read operations are performed, on a non-volatile memory device, after a power-on condition following a power-off condition on the non-volatile memory device;
determine, using a machine learning model, a change in threshold voltages associated with the two overlapped charge states after the power-off condition,
wherein the change in threshold voltages is determined based on detecting the read errors,
wherein the machine learning model is trained using characterization data that identifies different changes in threshold voltages for different data retention conditions for the two overlapped charge states of one or more non-volatile memory devices, and
wherein the machine learning model is trained to determine changes in threshold voltages for the two overlapped charge states after power-on conditions following power-off conditions; and
adjust, based on the change in threshold voltages, the pre-determined threshold voltages to obtain adjusted threshold voltages,
wherein subsequent read operations are performed on the non-volatile memory device using the adjusted threshold voltages.

10. The system of claim 9, wherein the machine learning model comprises a neural network model.

11. The system of claim 9, wherein the controller is to:
perform a lookup operation of a data structure, based on the change in threshold voltages, to determine threshold voltages of other charge states after the power-off condition.

12. The system of claim 9, wherein the controller is to:
perform a mathematical operation, using the change in threshold voltages, to determine threshold voltages of other charge states after the power-off condition.

13. The system of claim 9, wherein the controller is to:
perform, for a block of the non-volatile memory device, additional read operations to determine threshold voltages associated with the two overlapped charge states;
determine a health of the block based on the additional read operations and the change in threshold voltages associated with the two overlapped charge states; and
determine, based on the health of the block, that a refresh operation is to be performed on the block.

14. The system of claim 9, wherein the controller is to:
analyze program/erase information identifying dates and times of program/erase cycles of a plurality of blocks of the non-volatile memory device; and
identify one or more blocks as blocks with most recent program/erase cycles based on analyzing the program/erase information.

15. A computer program product comprising:
one or more computer readable storage media, and program instructions collectively stored on the one or more computer readable storage media, the program instructions comprising:
program instructions to detect read errors based on read operations performed using threshold voltages associated with two overlapped charge states,
wherein the read operations are performed after a power-on condition following a power-off condition on a non-volatile memory device, and
wherein the read operations are performed on one or more blocks of the non-volatile memory device; and
program instructions to determine, using a machine learning model, a change in threshold voltages associated with the two overlapped charge states after the power-off condition,
wherein the machine learning model is trained using characterization data that identifies different changes in threshold voltages for different data retention conditions for the two overlapped charge states of one or more non-volatile memory devices,
wherein the machine learning model is trained to determine changes in threshold voltages for the two overlapped charge states, after power-off conditions, and
wherein subsequent read operations are performed on the one or more blocks based on the change in threshold voltages.

16. The computer program product of claim 15, wherein the program instructions comprise:
program instructions to analyze program/erase information identifying dates and times of program/erase cycles of a plurality of blocks of the non-volatile memory device; and
program instructions to identify the one or more blocks as blocks, of the plurality of blocks, with most recent program/erase cycles based on analyzing the program/erase information.

17. The computer program product of claim 15, wherein the program instructions comprise:
program instructions to perform, for a block of the non-volatile memory device, additional read operations to determine threshold voltages associated with the two overlapped charge states;
program instructions to determine a health of the block based on the additional read operations and the change in threshold voltages associated with the two overlapped charge states; and
program instructions to determine, based on the health of the block, that a refresh operation is to be performed on the block.

18. The computer program product of claim 15, wherein the program instructions comprise:
program instructions to perform a mathematical operation, using the change in threshold voltages, to determine threshold voltages of other charge states after the power-off condition.

19. The computer program product of claim 15, wherein the program instructions comprise:
program instructions to a lookup operation of a data structure, based on the change in threshold voltages, to determine threshold voltages of other charge states after the power-off condition.

20. The computer program product of claim 15, wherein the machine learning model comprises a neural network model.
